(19) United States
(12) Patent Application Publication
(10) Pub. No.: US 2008/0242023 A1
(43) Pub. Date: Oct. 2, 2008

(54) METHOD FOR PREPARING A METAL-OXIDE-SEMICONDUCTOR TRANSISTOR

(75) Inventor: Huai An Huang, Taipei City (TW)

Correspondence Address: WPAT, PC;INTELLECTUAL PROPERTY ATTORNEYS, 2030 MAIN STREET, SUITE 1300, IRVINE, CA, 92614, US

(73) Assignee: PROMOS TECHNOLOGIES INC., Hsinchu (TW)

(21) Appl. No.: 11/747,111

(22) Filed: May 10, 2007

(30) Foreign Application Priority Data
Mar. 30, 2007 (TW) 096111203

(51) Int. Cl. H01L 21/336

(52) U.S. Cl. 438/257; 257/E21.409

(57) ABSTRACT

A method for preparing a Metal-Oxide-Semiconductor (MOS) transistor comprises the steps of forming a gate oxide layer on a substrate, forming a gate and a first dielectric layer on the gate oxide layer, forming a second dielectric layer on the sidewall of the gate, forming a third dielectric layer covering the first and the second dielectric layers, performing a first etching process to remove a portion of the third dielectric layer and performing a second etching process to form a spacer on the sidewall of the gate. The etching selectivity of the first etching process to the third dielectric layer and to the second dielectric layer is different from that of the second etching process such that the thickness of the second dielectric layer at the center of the substrate is smaller than the thickness of the second dielectric layer at the edge of the substrate.

### BACKGROUND OF THE INVENTION

(A) Field of the Invention

The present invention relates to a method for preparing a metal-oxide-semiconductor (MOS) transistor, and more particularly, to a method for preparing a metal-oxide-semiconductor transistor by using a multi-step etching technique to reverse the thickness distribution of a liner oxide layer for adjusting the electronic properties of the MOS transistor.

(B) Description of the Related Art

A MOS transistor comprises a gate, a drain and a source, and the gate serves as the switch of the MOS transistor, which turns on or off according to the applied voltage on the gate. Current semiconductor fabrication methods utilize spacers made of dielectric material on two sides of the gate, and the spacers serve as the electric insulation and the mask for the subsequent implanting process.

FIG. 1 and FIG. 2 illustrate a method for preparing a MOS transistor 30 according to the prior art. A gate oxide layer 12 is first formed on a substrate 10, and a gate 14 and a silicon nitride layer 15 are then formed on the gate oxide layer 12. Subsequently, an implanting process is performed to form two light doped regions 16 in the substrate 10 at either side of the gate 14, a thermal treating process is performed to form a liner oxide layer 18 at the sidewalls of the gate 14, and a low pressure chemical vapor phase deposition process is performed to form a silicon nitride layer 20 covering the liner oxide layer 18 and the silicon nitride layer 15.

Referring to FIG. 2, an anisotropic dry etching process is performed to remove a portion of the silicon nitride layer 20 on the silicon nitride layer 15 and the liner oxide layer 18 so as to form spacers 22 on two sides of the gate 14. Subsequently, spacers 22 are used as the implanting mask to perform an implanting process to form two heavy doped regions 24 in the substrate 10 at two sides of the spacers 22 to complete the MOS transistor 30. The doped concentration and depth of the heavy doped regions 24 influence the electronic properties of the MOS transistor 30, such as the threshold voltage, and the thickness of the liner oxide 18 influences the doped concentration and depth of the heavy doped regions 24, i.e., the thickness uniformity of the liner oxide layer 18 influences the electronic properties of the MOS transistor 30.

FIG. 3 illustrates the thickness distribution of the liner oxide layer 18 on the surface of the substrate 10. The thickness of the liner oxide layer 18 at the center of the substrate 10 (about 59 angstroms) is obviously larger than that at the edge of the substrate 10 (40.1 angstroms, 47.7 angstroms, 49.5 angstroms and 52.5 angstroms), i.e., the thickness distribution of the liner oxide layer 18 is thicker at the center and thinner at the edge of the substrate 10. This non-uniform thickness distribution of the liner oxide layer 18 causes the electronic properties of the MOS transistor 30 at the center of the substrate 10 to be different from those at the edge of the substrate 10.

### SUMMARY OF THE INVENTION

One aspect of the present invention provides a method for preparing a MOS transistor by using a multi-step etching technique to reverse the thickness distribution of a liner oxide layer, which can be used to adjust the electronic properties of the MOS transistor.

A method for preparing a MOS transistor according to this aspect of the present invention comprises the steps of forming a gate oxide layer on a substrate, forming a gate and a first dielectric layer on the gate oxide layer, forming a second dielectric layer on a sidewall of the gate, forming a third dielectric layer covering the first dielectric layer and the second dielectric layer, performing a first etching process to remove a portion of the third dielectric layer, and performing a second etching process to form a spacer on the sidewall of the gate. The etching selectivity of the first etching process to the third dielectric layer and the second dielectric layer is different from that of the second etching process.

Another aspect of the present invention provides a method for preparing a MOS transistor comprising the steps of forming a gate oxide layer on a substrate, forming a gate and a first dielectric layer on the gate oxide layer, forming a second dielectric layer on a surface of the substrate and a sidewall of the gate, forming a third dielectric layer covering the first dielectric layer and the second dielectric layer, removing a portion of the third dielectric layer to form a spacer on the sidewall of the gate and removing a portion of the second dielectric layer such that the thickness of the second dielectric layer at the center of the substrate is smaller than the thickness of the second dielectric layer at the edge of the substrate

The thickness distribution of the liner oxide layer is thicker at the center and thinner at the edge of the substrate according to the prior art. The present invention can reverse the thickness distribution of the liner oxide layer such that the thickness of the liner oxide layer is thinner at the center and thicker at the edge of the substrate. In particular, the liner oxide layer can be used as the implanting barrier layer for the subsequent implanting process to adjust the implanting concentration and depth so as to adjust the distribution of the electronic properties of the MOS transistor.

### BRIEF DESCRIPTION OF THE DRAWINGS

The objectives and advantages of the present invention will become apparent upon reading the following description and upon reference to the accompanying drawings in which:

FIG. 1 and FIG. 2 illustrate a method for preparing a MOS transistor according to the prior art;

FIG. 3 illustrates the thickness distribution of the liner oxide layer on the surface of the substrate according to the prior art;

FIG. 4 to FIG. 7 illustrate a method for preparing a MOS transistor according to one embodiment of the present invention; and

FIG. 8 illustrates the thickness distribution of the liner oxide layer on the surface of the substrate 40 according to the present invention.

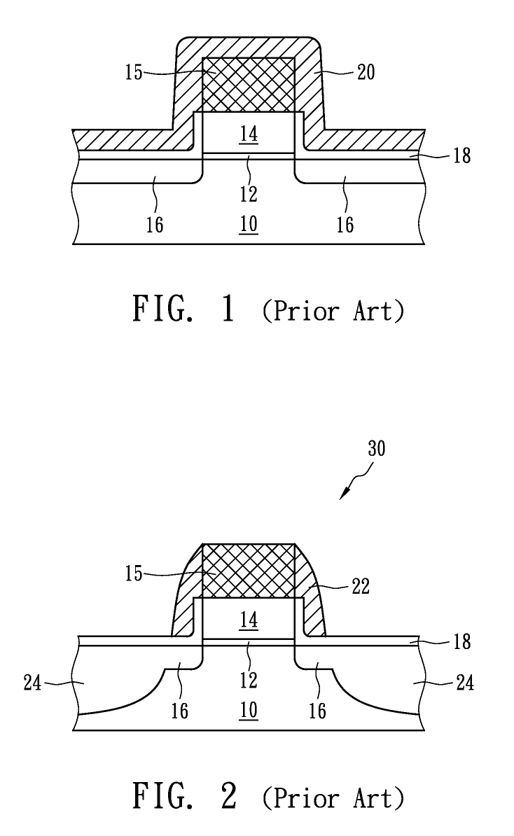

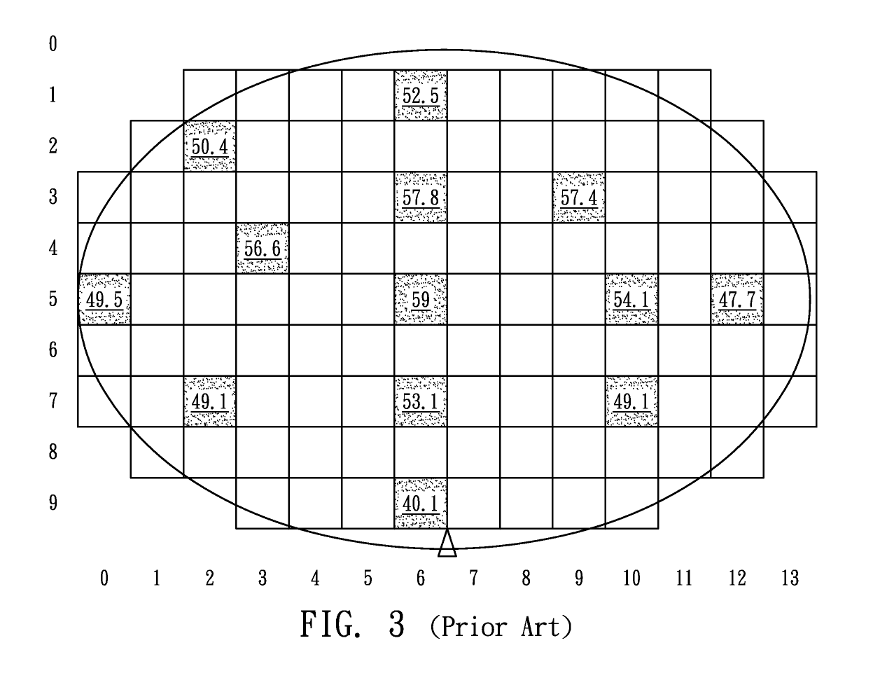

### DETAILED DESCRIPTION OF THE INVENTION

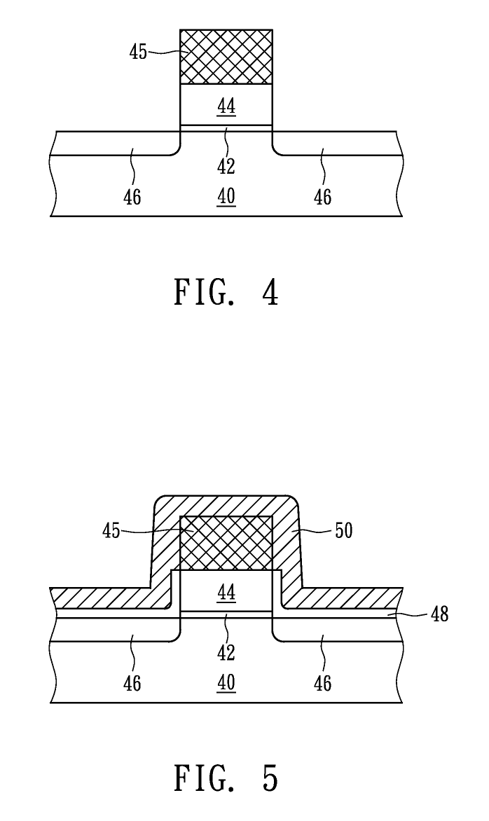

FIG. 4 to FIG. 7 illustrate a method for preparing a MOS transistor 60 according to one embodiment of the present invention. A gate oxide layer 42 is formed on a substrate 40 such as a silicon substrate, and a gate 44 and a first dielectric layer 45 are formed on the gate oxide layer 42. An implanting process is then performed to form two light doped regions 46 in the substrate at two sides of the gate 44. The gate 44 includes a polysilicon layer and a tungsten silicide layer (not shown in the drawings), and the first dielectric layer 45 is a silicon nitride layer. Subsequently, a thermal treating process is performed to a second dielectric layer (liner oxide layer) 48 on sidewalls of the gate 44 and on the surface of the substrate 40, and a low pressure chemical vapor phase deposition process is performed to form a third dielectric layer (silicon nitride layer) 50 covering the first dielectric layer 45 and the second dielectric layer 48, as shown in FIG. 5.

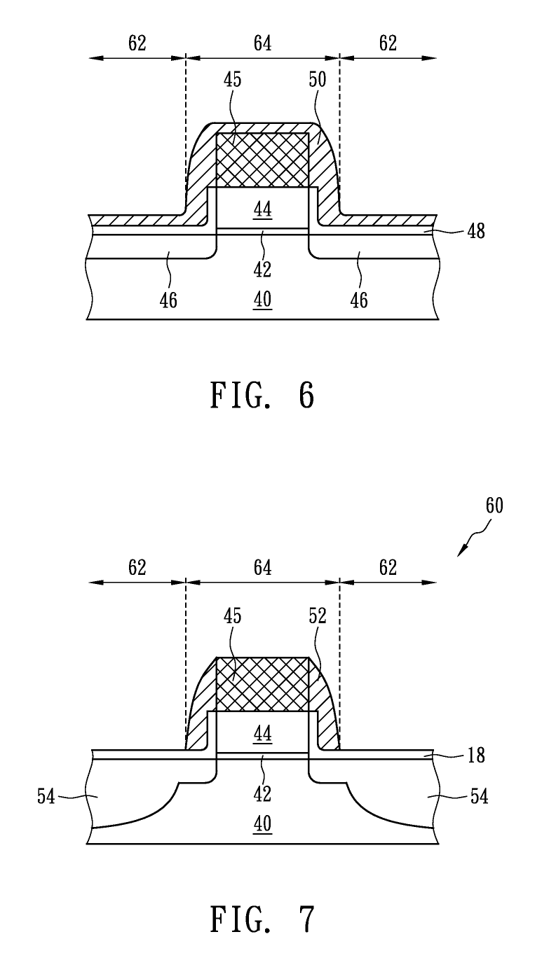

Referring to FIG. 6, a first etching process is performed to remove a portion of the third dielectric layer 50. The first etching process can be a dry etching process using etching gases including trifluoromethane to remove about 45% to 95% of the third dielectric layer 50 in the predetermined region 62, i.e., the first etching process preferably reduces the thickness of the third dielectric layer 50 in the predetermined region 62 by 45% to 95%. Subsequently, a second etching process is performed to remove a portion of the third dielectric layer 50 to form a spacer 52 on the sidewall of the gate 44. The second etching process can be a dry etching process using etching gases including methyl fluoride to remove about 5% to 55% of the third dielectric layer 50 in the predetermined region 62. In particular, the second etching process completely removes the third dielectric layer 50 in the predetermined region 62, and the third dielectric layer 50 in the predetermined region 64 forms the spacer 52.

The etching process for preparing the spacer 52 also removes a portion of the second dielectric layer 48 such that the thickness of the second dielectric layer 48 at the center of the substrate 40 is smaller than the thickness of the second dielectric layer 48 at the edge of the substrate 40. Subsequently, an implanting process is performed by using the spacer 52 as the implanting mask to form two heavy doped regions 54 in the substrate 40 at two sides of the spacer 52 to complete the MOS transistor 60, as shown in FIG. 7.

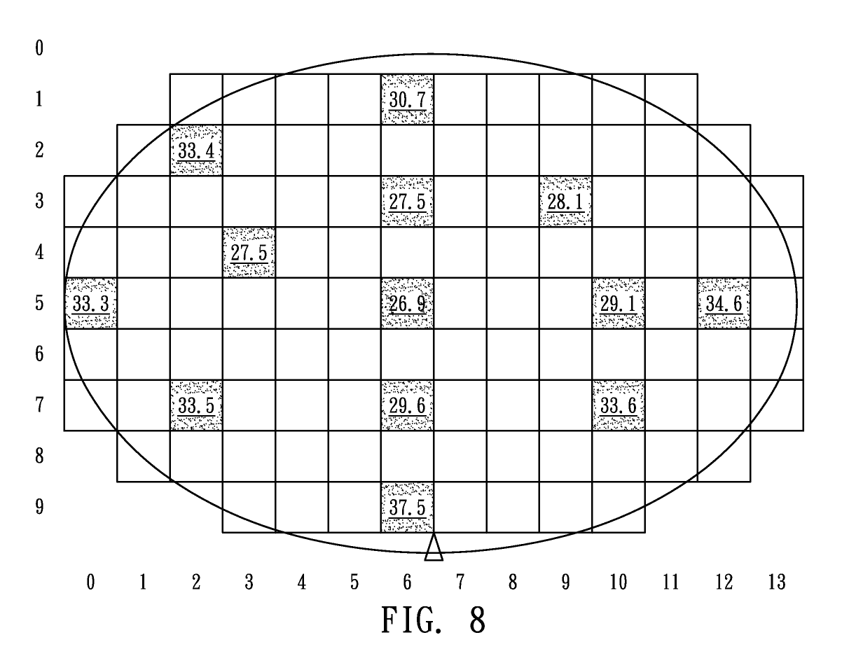

FIG. 8 illustrates the thickness distribution of the liner oxide layer 48 on the surface of the substrate 40 according to the present invention. The etching selectivity of the first etching process to the third dielectric layer 50 and the second dielectric layer 48 is different from that of the second etching process. For example, the etching selectivity of the first etching process to the third dielectric layer 50 and the second dielectric layer 48 is larger than that of the second etching process, i.e., the etching ability of the second etching process to the second dielectric layer 48 is very small. In addition, the etching rate of the first etching process to the third dielectric layer 50 is higher than that of the second etching process to the third dielectric layer 50. Consequently, the thickness of the second dielectric layer (liner oxide layer) 48 is 26.9 angstroms at the center and 30.7 angstroms, 33.3 angstroms, 34.6 angstroms and 37.5 angstroms at the edge of the substrate 40. In other words, the thickness distribution of the liner oxide layer 48 is such that the thickness of the liner oxide layer 48 is thinner at the center and thicker at the edge of the substrate 40, as shown in FIG. 8.

The thickness distribution of the liner oxide layer 18 is thicker at the center and thinner at the edge of the substrate 10 according to the prior art. The present invention can reverse the thickness distribution of the liner oxide layer 48 such that the thickness of the liner oxide layer 48 is thinner at the center and thicker at the edge of the substrate 40. In particular, the liner oxide layer 48 can be used as the implanting barrier layer for the subsequent implanting process to adjust the implanting concentration and depth so as to adjust the distribution of the electronic properties of the MOS transistor 60.

The above-described embodiments of the present invention are intended to be illustrative only. Numerous alternative embodiments may be devised by those skilled in the art without departing from the scope of the following claims.

What is claimed is:

1. A method for preparing a metal-oxide-semiconductor transistor, comprising the steps of:
forming a gate oxide layer on a substrate;
forming a gate and a first dielectric layer on the gate oxide layer;
forming a second dielectric layer on a sidewall of the gate;
forming a third dielectric layer covering the first dielectric layer and the second dielectric layer;
performing a first etching process to remove a portion of the third dielectric layer; and
performing a second etching process to form a spacer on the sidewall of the gate, wherein the etching selectivity of the first etching process to the third dielectric layer and the second dielectric layer is different from that of the second etching process.

2. The method for preparing a metal-oxide-semiconductor transistor of claim 1, wherein the first etching process is a dry etching process.

3. The method for preparing a metal-oxide-semiconductor transistor of claim 1, wherein the first etching process uses etching gases including trifluoromethane.

4. The method for preparing a metal-oxide-semiconductor transistor of claim 1, wherein the second etching process is a dry etching process.

5. The method for preparing a metal-oxide-semiconductor transistor of claim 1, wherein the second etching process uses etching gases including methyl fluoride.

6. The method for preparing a metal-oxide-semiconductor transistor of claim 1, wherein the etching rate of the first etching process to the third dielectric layer is higher than that of the second etching process to the third dielectric layer.

7. The method for preparing a metal-oxide-semiconductor transistor of claim 1, further comprising a step of forming a doped region in the substrate at two sides of the spacer.

8. The method for preparing a metal-oxide-semiconductor transistor of claim 1, wherein the thickness of the second dielectric layer at the center of the substrate is smaller than the thickness of the second dielectric layer at the edge of the substrate after the first etching process and the second etching process are performed.

9. The method for preparing a metal-oxide-semiconductor transistor of claim 1, wherein the first dielectric layer is a liner oxide layer.

10. The method for preparing a metal-oxide-semiconductor transistor of claim 1, wherein the third dielectric layer is a silicon nitride layer.

11. A method for preparing a metal-oxide-semiconductor transistor, comprising the steps of:
forming a gate oxide layer on a substrate;
forming a gate and a first dielectric layer on the gate oxide layer;
forming a second dielectric layer on a surface of the substrate and a sidewall of the gate;
forming a third dielectric layer covering the first dielectric layer and the second dielectric layer; and
removing a portion of the third dielectric layer to form a spacer on the sidewall of the gate and removing a portion of the second dielectric layer such that the thickness of the second dielectric layer at the center of the substrate is smaller than the thickness of the second dielectric layer at the edge of the substrate.

12. The method for preparing a metal-oxide-semiconductor transistor of claim 11, wherein the step of removing a portion of the third dielectric layer to form a spacer on the sidewall of the gate includes:
performing a first etching process to remove a portion of the third dielectric layer; and
performing a second etching process to remove a portion of the third dielectric layer to form the spacer on the sidewall of the gate, wherein the etching selectivity of the first etching process to the third dielectric layer and the second dielectric layer is different from that of the second etching process.

13. The method for preparing a metal-oxide-semiconductor transistor of claim 12, wherein the first etching process is a dry etching process.

14. The method for preparing a metal-oxide-semiconductor transistor of claim 12, wherein the first etching process uses etching gases including trifluoromethane.

15. The method for preparing a metal-oxide-semiconductor transistor of claim 12, wherein the second etching process is a dry etching process.

16. The method for preparing a metal-oxide-semiconductor transistor of claim 12, wherein the second etching process uses etching gases including methyl fluoride.

17. The method for preparing a metal-oxide-semiconductor transistor of claim 12, wherein the etching rate of the first etching process to the third dielectric layer is higher than that of the second etching process to the third dielectric layer.

18. The method for preparing a metal-oxide-semiconductor transistor of claim 11, further comprising a step of forming a doped region in the substrate at two sides of the spacer.

19. The method for preparing a metal-oxide-semiconductor transistor of claim 11, wherein the first dielectric layer is a liner oxide layer.

20. The method for preparing a metal-oxide-semiconductor transistor of claim 1, wherein the third dielectric layer is a silicon nitride layer.
